(19) United States
(12) Patent Application Publication
(10) Pub. No.: US 2026/0181986 A1
(43) Pub. Date: Jun. 25, 2026

(54) SEMICONDUCTOR DEVICE AND METHOD FOR MANUFACTURING THE SAME

(71) Applicant: SK hynix Inc., Gyeonggi-do (KR)

(72) Inventors: Dong Chan SUH, Gyeonggi-do (KR); Hai Won KIM, Gyeonggi-do (KR); Jeong Hyun LEE, Gyeonggi-do (KR)

(21) Appl. No.: 19/208,563

(22) Filed: May 14, 2025

(30) Foreign Application Priority Data
Dec. 19, 2024 (KR) 10-2024-0190937

(51) Int. Cl. H10D 64/23; H10D 30/01; H10D 64/27; H10D 84/01

(52) U.S. Cl. CPC H10D 64/254; H10D 30/021; H10D 64/511; H10D 84/0149

(57) ABSTRACT

A semiconductor device comprises a substrate, a channel area formed in a part of the substrate, a source area and a drain area spaced apart from each other penetrating the substrate, and connected to the channel area, a gate insulation layer on the part of the substrate in a first direction, a gate electrode disposed on the gate insulation layer, a gate contact connected to the gate electrode, and a source contact and a drain contact respectively connected to the source area and the drain area under the substrate in a second direction opposite to the first direction.

### CROSS-REFERENCES TO RELATED APPLICATION

The present application claims priority under 35 U.S.C. 119(a) to Korean patent application number 10-2024-0190937 filed on December 19, 2024, which is incorporated herein by reference in its entirety.

### TECHNICAL FIELD

Embodiments of the present disclosure relate to a semiconductor device and a method for manufacturing the same.

### BACKGROUND

Due to their miniaturization, multi-functionality, and/or low manufacturing cost characteristics, semiconductor devices are attracting attention as important components in the electronics industry. As the electronics industry advances, semiconductor devices are becoming increasingly highly integrated. For these highly integrated semiconductor devices, the width of the lines included in the semiconductor device is gradually decreasing, making it more difficult in forming the transistor included in the semiconductor device.

### SUMMARY

Embodiments of the present disclosure provide a semiconductor device capable of high integration without performance deterioration of a transistor and a method for manufacturing the same.

Embodiments of the present disclosure are not limited to those set forth herein, and other unmentioned embodiments would be apparent to one of ordinary skill in the art from the following description.

Embodiments of the present disclosure may provide a semiconductor device comprising a substrate, a channel area formed in a part of the substrate, a source area and a drain area spaced apart from each other penetrating the substrate, and connected to the channel area, a gate insulation layer on the part of the substrate in a first direction, a gate electrode disposed on the gate insulation layer, a gate contact connected to the gate electrode, and a source contact and a drain contact respectively connected to the source area and the drain area under the substrate in a second direction opposite to the first direction.

Embodiments of the present disclosure may provide a semiconductor device comprising a first semiconductor structure and a second semiconductor structure bonded to each other. The first semiconductor structure includes a first bonding insulation layer, a first substrate disposed on the first bonding insulation layer, a channel area formed in a part of the first substrate, a first source area and a first drain area spaced apart from each other penetrating the first substrate and the first bonding insulation layer and connected to the channel area, a gate electrode positioned on the first substrate, and a gate contact connected to the gate electrode. The second semiconductor structure includes a second bonding insulation layer connected to a lower surface of the first bonding insulation layer, a second substrate disposed under the second bonding insulation layer, a second source area and a second drain area penetrating the second substrate and the second bonding insulation layer and respectively connected to the first source area and the first drain area, and a source contact and a drain contact connected to the second source area and the second drain area, respectively.

Embodiments of the present disclosure may provide a method for manufacturing a semiconductor device comprising preparing a first substrate having an upper surface on which a channel area, and a first semiconductor area and a second semiconductor area connected to the channel area are formed, forming, on the upper surface of the first substrate, a gate electrode and a gate contact connected to the gate electrode, exposing lower surfaces of the first semiconductor area and the second semiconductor area, and forming a source contact and a drain contact connected to the first semiconductor area and the second semiconductor area, respectively.

According to embodiments of the present disclosure, it is possible to highly integrate the semiconductor device without performance deterioration of the transistor.

The advantages of the embodiments of the present disclosure are not limited to the foregoing advantages, and other advantages will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a view illustrating a semiconductor device according to embodiments of the present disclosure.

FIGS. 2 and 3 are views illustrating another semiconductor device according to embodiments of the present disclosure.

FIGS. 4 to 8 are views illustrating a method for manufacturing a semiconductor device according to embodiments of the present disclosure.

FIGS. 9 to 19 are views illustrating another method for manufacturing a semiconductor device according to embodiments of the present disclosure.

### DETAILED DESCRIPTION

Hereinafter, embodiments of the present disclosure are described in detail with reference to the accompanying drawings. In assigning reference numerals to components of each drawing, the same components may be assigned the same numerals even when they are shown on different drawings. When it is determined that the subject matter of the present disclosure will be unclear, the details of the known art or functions may be skipped. As used herein, when a component “includes” another component, the component may add other components unless the term “only” is used with “includes, has, or is composed of”. As used herein, the singular forms “a,” “an,” and “the” are intended to include the plural forms as well, unless the context clearly indicates otherwise.

Labels, such as "first" and "second," may be used in describing the components of the disclosure. These labels are provided merely to distinguish a component from another, and the essence, order, or number of the components are not limited by the labels.

In describing the positional relationship between components, when two or more components are described as "connected” or "coupled", the two or more components may be directly "connected” or "coupled" ", or another component may intervene. Here, the other component may be included in one or more of the two or more components that are “connected” or “coupled” to each other.

In describing temporal relationships between components, operation methods, or manufacturing methods, the cases of being not continuous may be included, unless "directly" or "immediately" is used.

If a numerical value or its corresponding information (e.g., level, etc.) is mentioned for a component, it may be interpreted that the numerical value or its corresponding information includes a margin of error that may be caused by various factors (e.g., process factors, internal or external shocks, noise, etc.), even if it is not explicitly stated otherwise.

Hereinafter, various embodiments of the present disclosure will be described in detail with reference to accompanying drawings.

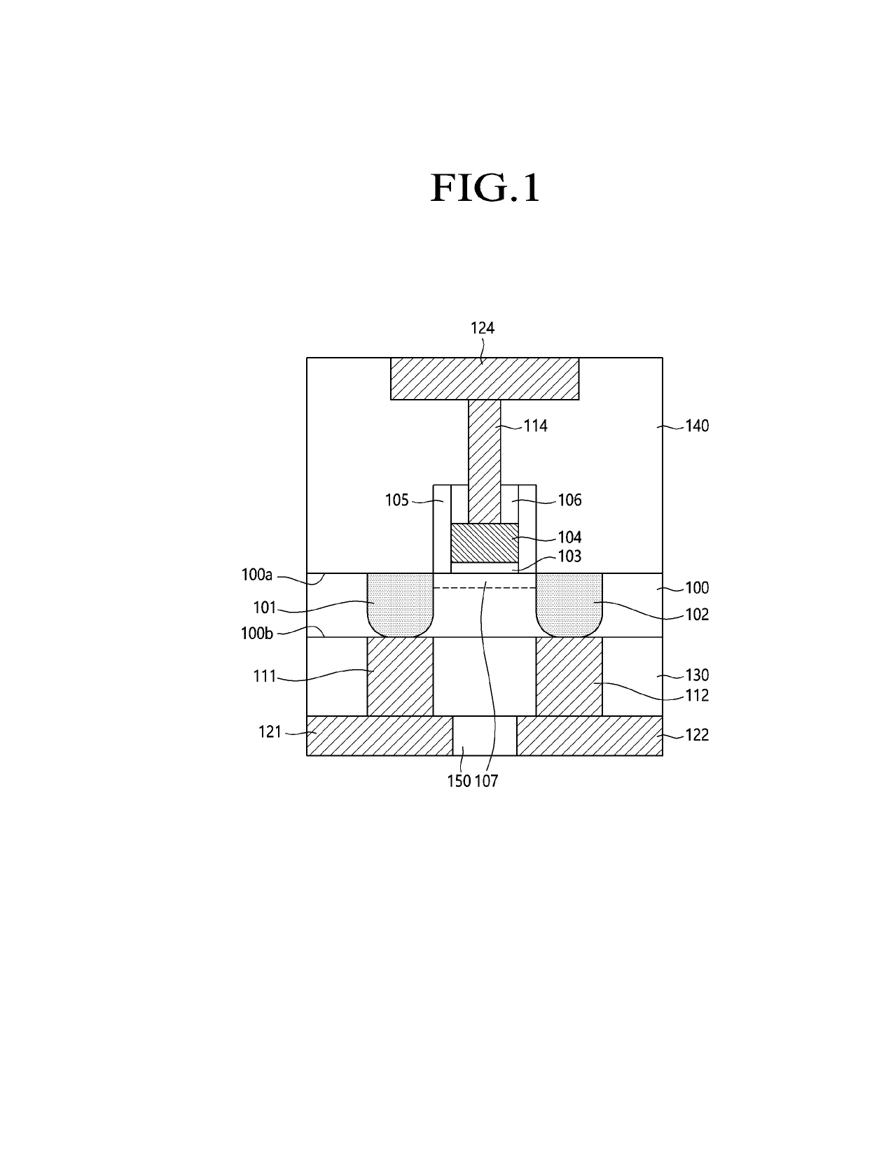

FIG. 1 is a view illustrating a semiconductor device according to embodiments of the present disclosure.

Referring to FIG. 1, the semiconductor device includes a substrate 100, a transistor TR, a spacer 105, a gate capping layer 106, a gate contact 114, a gate line 124, a source contact 111, a source line 121, a drain contact 112, a drain line 122, a first insulation layer 130, a second insulation layer 140, and a third insulation layer 150.

The transistor TR includes a source area 101, a drain area 102, a gate insulation layer 103, a gate electrode 104, and a channel area 107.

The semiconductor device includes a memory, a processor, or a combination thereof. For example, the semiconductor device includes dynamic random access memory (DRAM), static random access memory (SRAM), flash memory, magnetoresistive random access memory (MRAM), phase-change random access memory (PRAM), ferroelectric random access memory (FRAM), resistive random access memory (RRAM), or a combination thereof. However, the semiconductor device is not limited to the above memories.

The transistor TR may be any of transistors included in the semiconductor device. For example, when the semiconductor device is a DRAM, the transistor TR may be any of transistors included in a peripheral circuit of the DRAM.

The substrate 100 includes a semiconductor substrate such as a silicon wafer or a silicon on insulator (SOI) wafer. The substrate 100 includes a group III-V semiconductor substrate, e.g., a compound semiconductor substrate such as GaAs. The substrate 100 includes mono-crystalline silicon, polysilicon, amorphous silicon, mono-crystalline silicon germanium, poly-crystalline silicon germanium, carbon-doped silicon, or a combination thereof.

The substrate 100 includes a first surface 100a and a second surface 100b facing each other. The first surface 100a may be referred to as a front surface of the substrate 100, and the second surface 100b may be referred to as a rear surface of the substrate 100.

In an embodiment, the thickness of the substrate 100 may be greater than or equal to 50 nm and less than or equal to 500 nm.

The channel area 107, the source area 101, and the drain area 102 are disposed in the substrate 100. The source area 101 and the drain area 102 are positioned on two opposite sides of the channel area 107. The source area 101 and the drain area 102 may be connected to the channel area 107 on two opposite sides, respectively, of the channel area 107.

The source area 101 and the drain area 102 may penetrate the substrate 100. For example, the upper surfaces of the source area 101 and the drain area 102 may form substantially the same plane as the first surface 100a of the substrate 100. The lower surfaces of the source area 101 and the drain area 102 may form substantially the same plane as the second surface 100b of the substrate 100.

In an embodiment, the widths of the source area 101 and the drain area 102 on the second surface 100b of the substrate 100 may be thinner than the widths of the source area 101 and the drain area 102 on the first surface 100a, respectively.

In an embodiment, the channel area 107 includes mono-crystalline silicon with P-type impurities. The P-type impurities include B, BF, BF2, or a combination thereof. In an embodiment, the source area 101 and the drain area 102 may be epitaxially grown layers. The source area 101 and the drain area 102 include silicon doped with carbon, phosphorus, or arsenic, silicon germanium, or boron-doped silicon germanium depending on the type (e.g., N-type or P-type) of the transistor TR.

On the first surface 100a of the substrate 100, the gate insulation layer 103 is disposed in an area overlapping the channel area 107. The gate insulation layer 103 includes silicon oxide, silicon nitride, silicon oxynitride, high-K dielectric, or a combination thereof.

The gate electrode 104 and the gate capping layer 106 are sequentially disposed on the gate insulation layer 103. The spacer 105 is disposed on the side surfaces of the gate insulation layer 103, the gate electrode 104, and the gate capping layer 106. Each of the spacer 105 and the gate capping layer 106 include silicon oxide, silicon nitride, silicon oxynitride, high-K dielectric, or a combination thereof.

The second insulation layer 140 may be disposed on the gate capping layer 106 and the spacer 105. The second insulation layer 140 includes silicon oxide, silicon nitride, silicon oxynitride, high-K dielectric, or a combination thereof.

One side of the gate contact 114 penetrates the gate capping layer 106 and is connected to the upper surface of the gate electrode 104. The other side of the gate contact 114 is connected to the gate line 124. The gate contact 114 and the gate line 124 include a metal, metal silicide, metal nitride, metal oxide, polysilicon, conductive carbon, or a combination thereof. FIG. 1 illustrates one gate contact 114 and one gate line 124 connected thereto, but the numbers of gate contacts 114 and gate lines 124 are not limited thereto.

The first insulation layer 130 is disposed under the source area 101 and the drain area 102. One side of the source contact 111 penetrates the first insulation layer 130 and is connected to the lower surface of the source area 101. In an embodiment, one side of the source contact 111 may be connected to the second surface 100b of the substrate 100. The third insulation layer 150 is disposed under the first insulation layer 130. The source line 121 and the drain line 122 penetrate the third insulation layer 150. The other side of the source contact 111 is connected to the source line 121. One side of the drain contact 112 is connected to the lower surface of the drain area 102. In an embodiment, one side of the drain contact 112 may be connected to the second surface 100b of the substrate 100. The other side of the drain contact 112 is connected to the drain line 122.

Each of the source contact 111, the drain contact 112, the source line 121, and the drain line 122 includes a metal, metal silicide, metal nitride, metal oxide, polysilicon, conductive carbon, or a combination thereof. FIG. 1 illustrates one source contact 111 and one drain contact 112 and one source line 121 and one drain line 122 respectively connected thereto, but the numbers of source and drain contacts 111 and 112 and source and drain lines 121 and 122 are not limited thereto. Each of the first insulation layer 130 and the third insulation layer 150 includes silicon oxide, silicon nitride, silicon oxynitride, high-K dielectric, or a combination thereof.

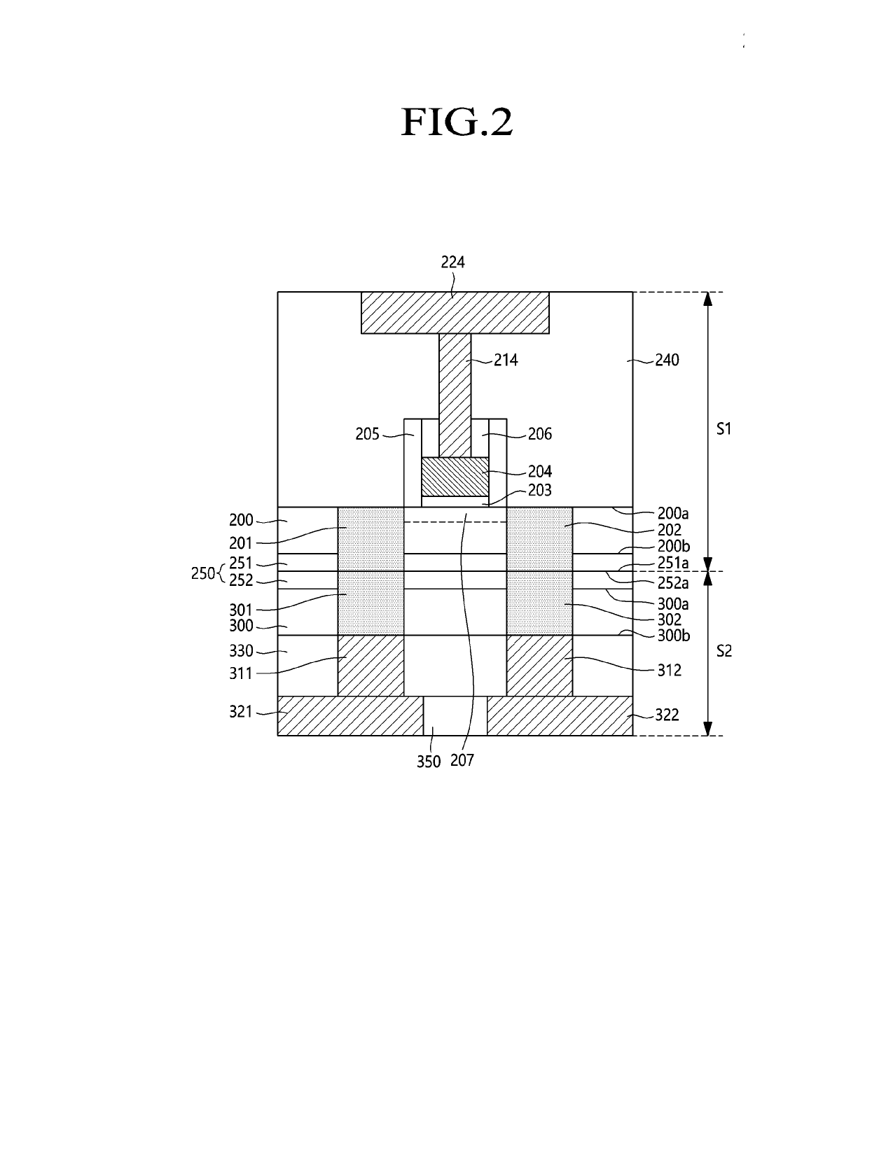

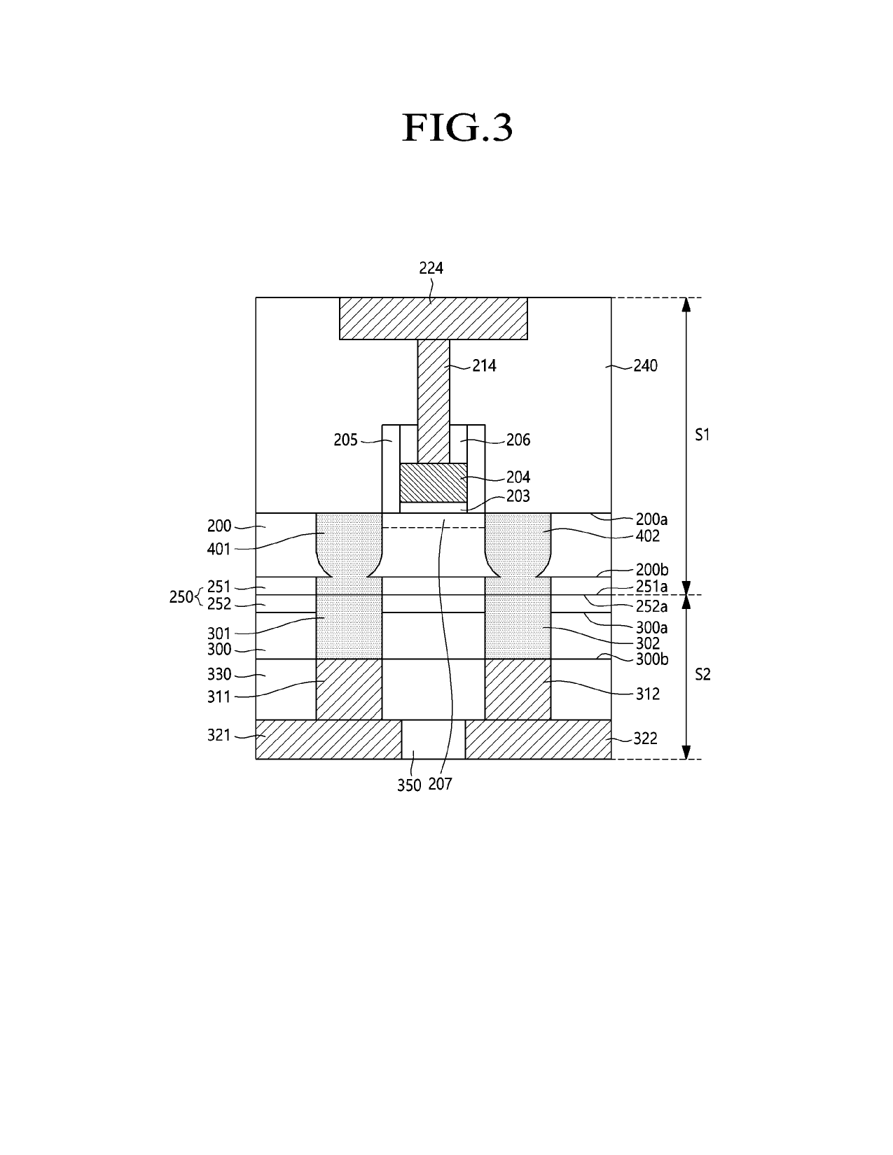

FIGS. 2 and 3 are views illustrating another semiconductor device according to embodiments of the present disclosure.

Referring to FIG. 2, the semiconductor device includes a first semiconductor structure S1 and a second semiconductor structure S2. The first semiconductor structure S1 and the second semiconductor structure S2 may be bonded to each other. In an embodiment, the first semiconductor structure S1 and the second semiconductor structure S2 may be different wafers.

The first semiconductor structure S1 includes a first substrate 200, a first bonding insulation layer 251, a first source area 201, a first drain area 202, a channel area 207, a gate insulation layer 203, a gate electrode 204, a gate capping layer 206, a spacer 205, a gate contact 214, a gate line 224, and a second insulation layer 240.

The second semiconductor structure S2 includes a second substrate 300, a second bonding insulation layer 252, a second source area 301, a second drain area 302, a first insulation layer 330, a source contact 311, a drain contact 312, a source line 321, a drain line 322, and a third insulation layer 350.

The first source area 201, the first drain area 202, the second source area 301, the second drain area 302, the channel area 207, the gate insulation layer 203, and the gate electrode 204 may constitute the transistor TR. The first source area 201 and the second source area 301 may constitute the source area of the transistor TR. The first drain area 202 and the second drain area 302 may constitute the drain area of the transistor TR. A bonding insulation layer 250 includes the first bonding insulation layer 251 and the second bonding insulation layer 252.

The first substrate 200 may be substantially the same as the substrate 100 described with reference to FIG. 1. The first substrate 200 includes a first surface 200a and a second surface 200b facing each other.

The channel area 207, the first source area 201, and the first drain area 202 are disposed in the first substrate 200. The first source area 201 and the first drain area 202 include the same material as the source area 101 and the drain area 102 described with reference to FIG. 1, respectively.

The first source area 201 and the first drain area 202 may penetrate the first substrate 200 and the first bonding insulation layer 251. For example, upper surfaces of the first source area 201 and the first drain area 202 may form substantially the same plane as the first surface 200a of the first substrate 200. The lower surfaces of the first source area 201 and the first drain area 202 may form substantially the same plane as the lower surface 251a of the first bonding insulation layer 251.

In an embodiment, the widths of the first source area 201 and the first drain area 202 on the first surface 200a of the first substrate 200 may be substantially the same as the widths of the first source area 201 and the first drain area 202 on the lower surface 251a of the first bonding insulation layer 251, respectively. In an embodiment, the widths of the first source area 201 and the first drain area 202 on the first surface 200a of the first substrate 200 may be substantially the same as the widths of the first source area 201 and the first drain area 202 on the second surface 200b of the first substrate 200, respectively.

The gate insulation layer 203, the gate electrode 204, and the gate capping layer 206 are sequentially stacked in an area overlapping the channel area 207 on the first substrate 200. The spacer 205 is disposed on the side surfaces of the gate insulation layer 203, the gate electrode 204, and the gate capping layer 206. The gate insulation layer 203, the gate electrode 204, the gate capping layer 206, and the spacer 207 may be substantially the same as the gate insulation layer 103, the gate electrode 104, the gate capping layer 106, and the spacer 107 described with reference to FIG. 1, respectively.

One side of the gate contact 214 penetrates the gate capping layer 206 and is connected to the upper surface of the gate electrode 204. The other side of the gate contact 214 is connected to the gate line 224. The second insulation layer 240 may be disposed on the gate contact 214, the gate line 224, and the spacer 205. The gate contact 214, the gate line 224, and the second insulation layer 240 may be substantially the same as the gate contact 114, the gate line 124, and the second insulation layer 140, respectively, described with reference to FIG. 1.

The second bonding insulation layer 252 is disposed under the first bonding insulation layer 251. The upper surface 252a of the second bonding insulation layer 252 is connected to the lower surface 251a of the first bonding insulation layer 251. The upper surface 252a of the second bonding insulation layer 252 and the lower surface 251a of the first bonding insulation layer 251 may refer to the same plane. Each of the first bonding insulation layer 251 and the second bonding insulation layer 252 include silicon oxide, silicon nitride, silicon carbide, or a combination thereof. Each of the first bonding insulation layer 251 and the second bonding insulation layer 252 include SiO2, SiOC, SiOCN, SiBN, SiBCN, SiN, or a combination thereof.

The second substrate 300 is disposed under the second bonding insulation layer 252. The second substrate 300 is disposed to be spaced apart from the first substrate 200. The second substrate 300 includes a semiconductor substrate such as a silicon wafer or a silicon on insulator (SOI) wafer. The second substrate 300 includes a group III-V semiconductor substrate, e.g., a compound semiconductor substrate such as GaAs. The second substrate 300 includes mono-crystalline silicon, polysilicon, amorphous silicon, mono-crystalline silicon germanium, poly-crystalline silicon germanium, carbon-doped silicon, or a combination thereof. In an embodiment, the second substrate 300 includes the same material as the first substrate 200.

The second substrate 300 includes a first surface 300a and a second surface 300b facing each other.

The second source area 301 and the second drain area 302 may penetrate the second substrate 300 and the second bonding insulation layer 252. For example, the lower surfaces of the second source area 301 and the second drain area 302 may form substantially the same plane as the second surface 300b of the second substrate 300. The upper surfaces of the second source area 301 and the second drain area 302 may form substantially the same plane as the upper surface 252a of the second bonding insulation layer 252.

In an embodiment, the widths of the second source area 301 and the second drain area 302 on the first surface 300a of the second substrate 300 may be substantially the same as the widths of the second source area 301 and the second drain area 302 on the upper surface 252a of the second bonding insulation layer 252. In an embodiment, the widths of the second source area 301 and the second drain area 302 on the first surface 300a of the second substrate 300 may be substantially the same as the widths of the second source area 301 and the second drain area 302 on the second surface 300b of the second substrate 300.

The upper surface of the second source area 301 is connected to the lower surface of the first source area 201. The upper surface of the second drain area 302 is connected to the lower surface of the first drain area 202. In an embodiment, the width of the second source area 301 may be substantially the same as the width of the first source area 201. In an embodiment, the width of the second drain area 302 may be substantially the same as the width of the first drain area 202.

The first insulation layer 330 is disposed under the second source area 301 and the second drain area 302. One side of the source contact 311 penetrates the first insulation layer 330 to be connected to the second source area 301. The upper surface of the source contact 311 is connected to the second source area 301. The third insulation layer 350 is disposed under the first insulation layer 330. The source line 321 and the drain line 322 penetrate the third insulation layer 350. The other side of the source contact 311 is connected to the source line 321. Similarly, one side of the drain contact 312 is connected to the second drain area 302. The upper surface of the drain contact 312 is connected to the second drain area 302. The other side of the drain contact 312 is connected to the drain line 322.

The first insulation layer 330 is disposed on side surfaces of the source contact 311 and the drain contact 312, the source line 321, and the drain line 322.

Referring to FIG. 3, the semiconductor device includes a first semiconductor structure S1 and a second semiconductor structure S2. The first semiconductor structure S1 and the second semiconductor structure S2 may be bonded to each other. In an embodiment, the first semiconductor structure S1 and the second semiconductor structure S2 may be different wafers.

The first semiconductor structure S1 includes a first substrate 200, a first bonding insulation layer 251, a first source area 401, a first drain area 402, a channel area 207, a gate insulation layer 203, a gate electrode 204, a gate capping layer 206, a spacer 205, a gate contact 214, a gate line 224, and a second insulation layer 240.

The second semiconductor structure S2 includes a second substrate 300, a second bonding insulation layer 252, a second source area 301, a second drain area 302, a first insulation layer 330, a source contact 311, a drain contact 312, a source line 321, a drain line 322, and a third insulation layer 350.

The first source area 401, the first drain area 402, the second source area 301, the second drain area 302, the channel area 207, the gate insulation layer 203, and the gate electrode 204 may constitute the transistor TR. The first source area 401 and the second source area 301 may constitute the source area of the transistor TR. The first drain area 402 and the second drain area 302 may constitute the drain area of the transistor TR. A bonding insulation layer 250 includes the first bonding insulation layer 251 and the second bonding insulation layer 252.

The channel area 207, the first source area 401, and the first drain area 402 are disposed in the first substrate 200. The first source area 401 and the first drain area 402 include the same material as the first source area 201 and the first drain area 202 described with reference to FIG. 2, respectively.

The first source area 401 and the first drain area 402 may penetrate the first substrate 200 and the first bonding insulation layer 251. For example, upper surfaces of the first source area 401 and the first drain area 402 may form substantially the same plane as the first surface 200a of the first substrate 200. The lower surfaces of the first source area 401 and the first drain area 402 may form substantially the same plane as the lower surface 251a of the first bonding insulation layer 251.

In an embodiment, the widths of the first source area 401 and the first drain area 402 on the first surface 200a of the first substrate 200 may be wider than the widths of the first source area 401 and the first drain area 402 on the second surface 200b of the first substrate 200, respectively. In an embodiment, the widths of the first source area 401 and the first drain area 402 on the second surface 200b of the first substrate 200 may be thinner than the widths of the first source area 401 and the first drain area 402 on the lower surface 251a of the first bonding insulation layer 251, respectively.

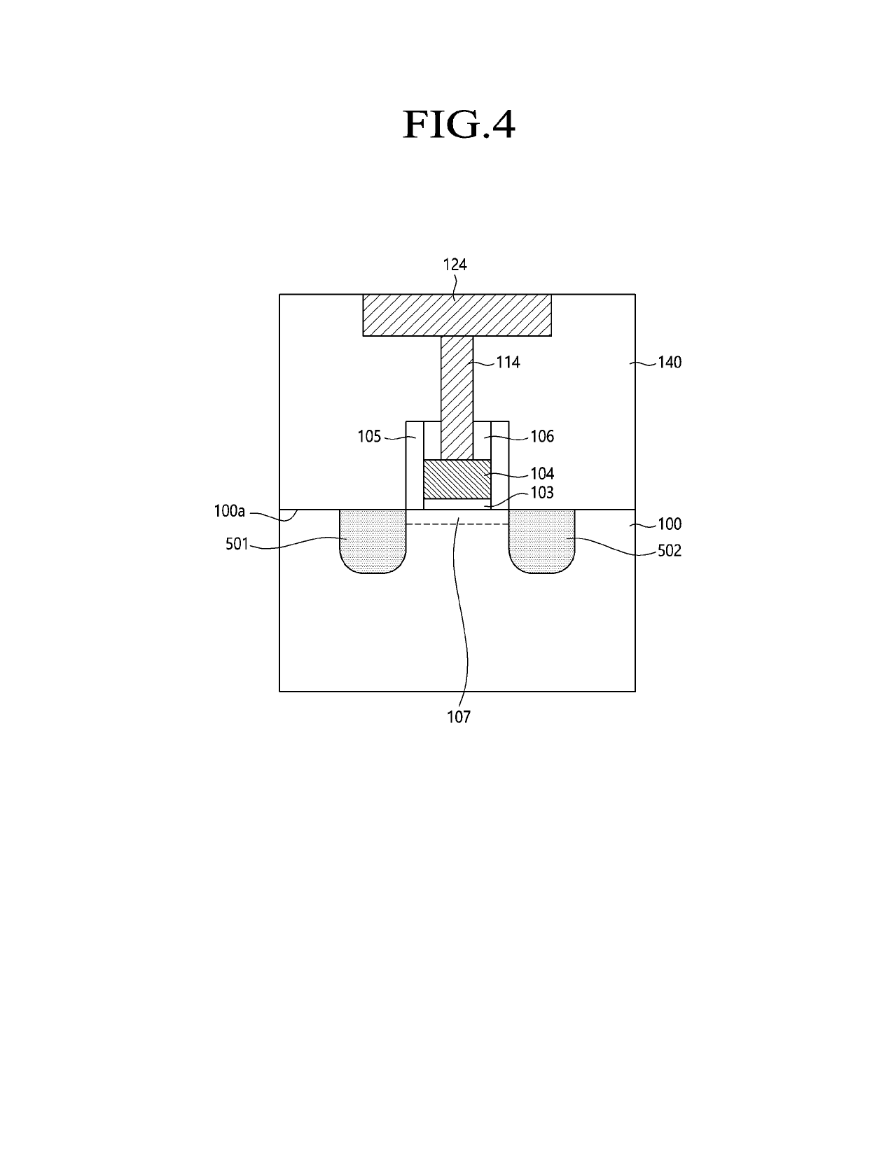

FIGS. 4 to 8 are views illustrating a method for manufacturing a semiconductor device according to embodiments of the present disclosure.

Referring to FIG. 4, a substrate 100 having a channel area 107 and a first semiconductor area 501 and a second semiconductor area 502 connected to the channel area 107 formed on a first surface 100a is prepared.

The first semiconductor area 501 and the second semiconductor area 502 may be epitaxially grown layers. Each of the first semiconductor area 501 and the second semiconductor area 502 include silicon doped with carbon, phosphorus, or arsenic, silicon germanium, or boron-doped silicon germanium depending on the type (e.g., N-type or P-type) of the transistor TR.

A gate insulation layer 103, a gate electrode 104, and a gate capping layer 106 are sequentially formed in an area overlapping the channel area 107 on the substrate 100. A spacer 105 is formed on the side surfaces of the gate insulation layer 103, the gate electrode 104, and the gate capping layer 106.

A gate contact 114 is formed to penetrate the gate capping layer 106 and be connected to the upper surface of the gate electrode 104. A gate line 124 is formed on the gate contact 114.

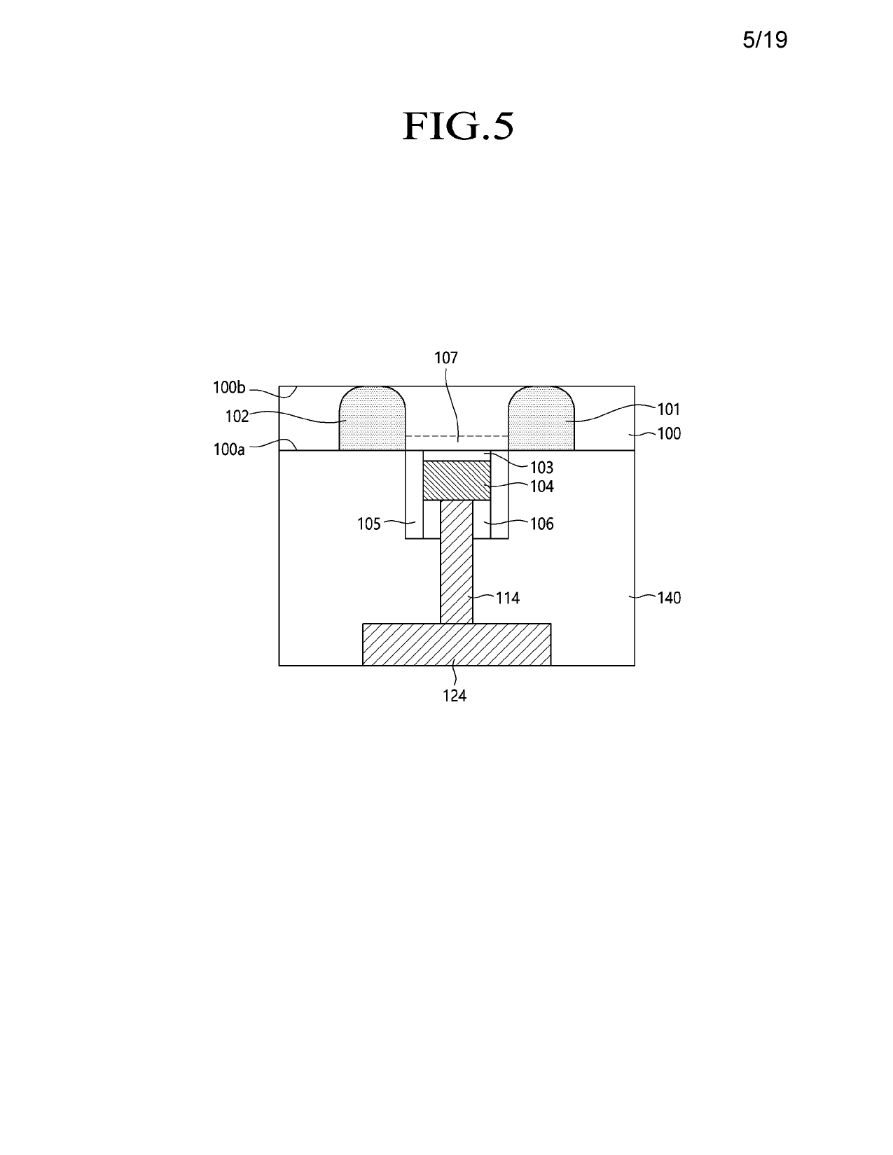

Referring to FIG. 5, the semiconductor device in FIG. 4 is flipped over. Referring to FIGS. 4 and 5, a lower portion of the substrate 100 is removed to expose the first semiconductor area 501 and the second semiconductor area 502. The process of removing the lower portion of the substrate 100 includes a chemical mechanical polishing (CMP) process or a grinding process.

As the lower portion of the substrate 100 is removed, at least a portion of the first semiconductor area 501 and the second semiconductor area 502 may be removed together to form a source area 101 and a drain area 102, respectively. In an embodiment, one surface (e.g., the upper surface) of the source area 101 and one surface (e.g., the upper surface) of the drain area 102 may form substantially the same plane as the second surface 100b of the substrate 100. In an embodiment, the widths of the source area 101 and the drain area 102 on the second surface 100b of the substrate 100 may be thinner than the widths of the source area 101 and the drain area 102 on the first surface 100a of the substrate 100, respectively.

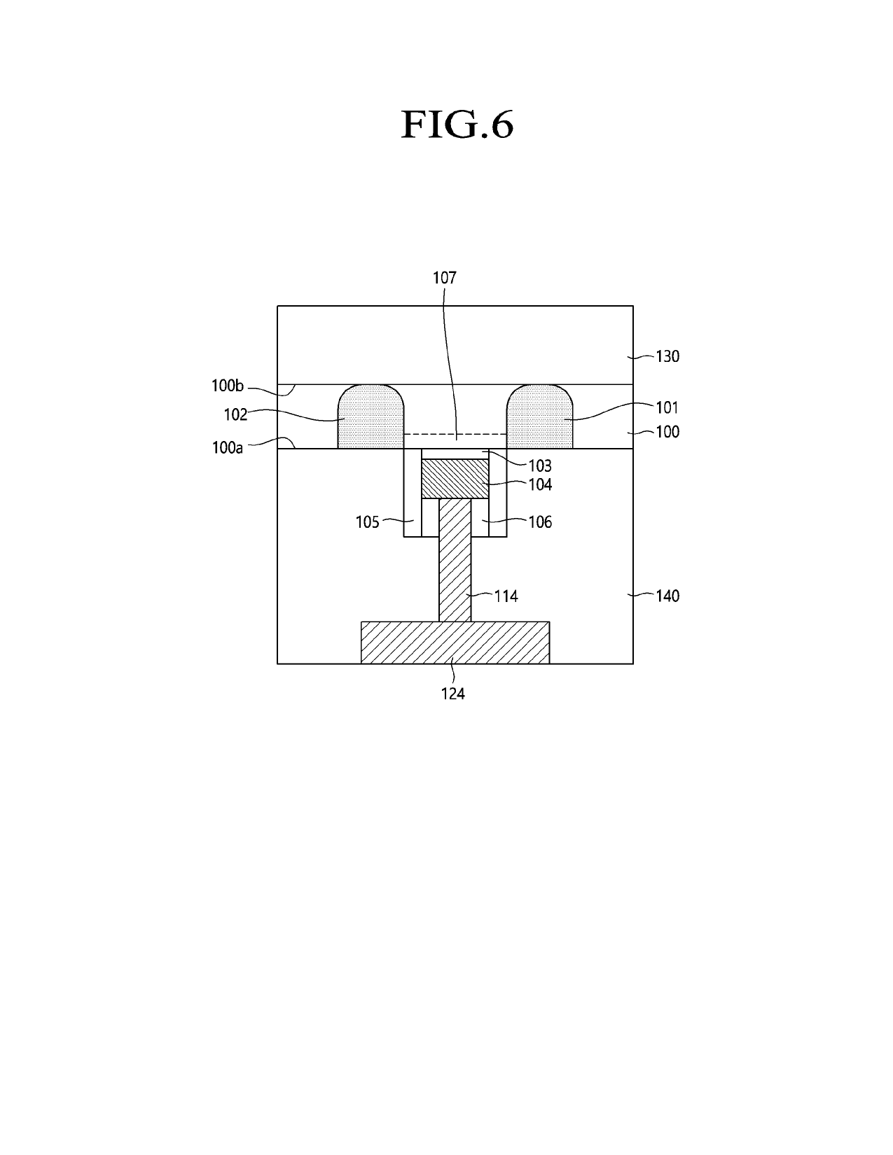

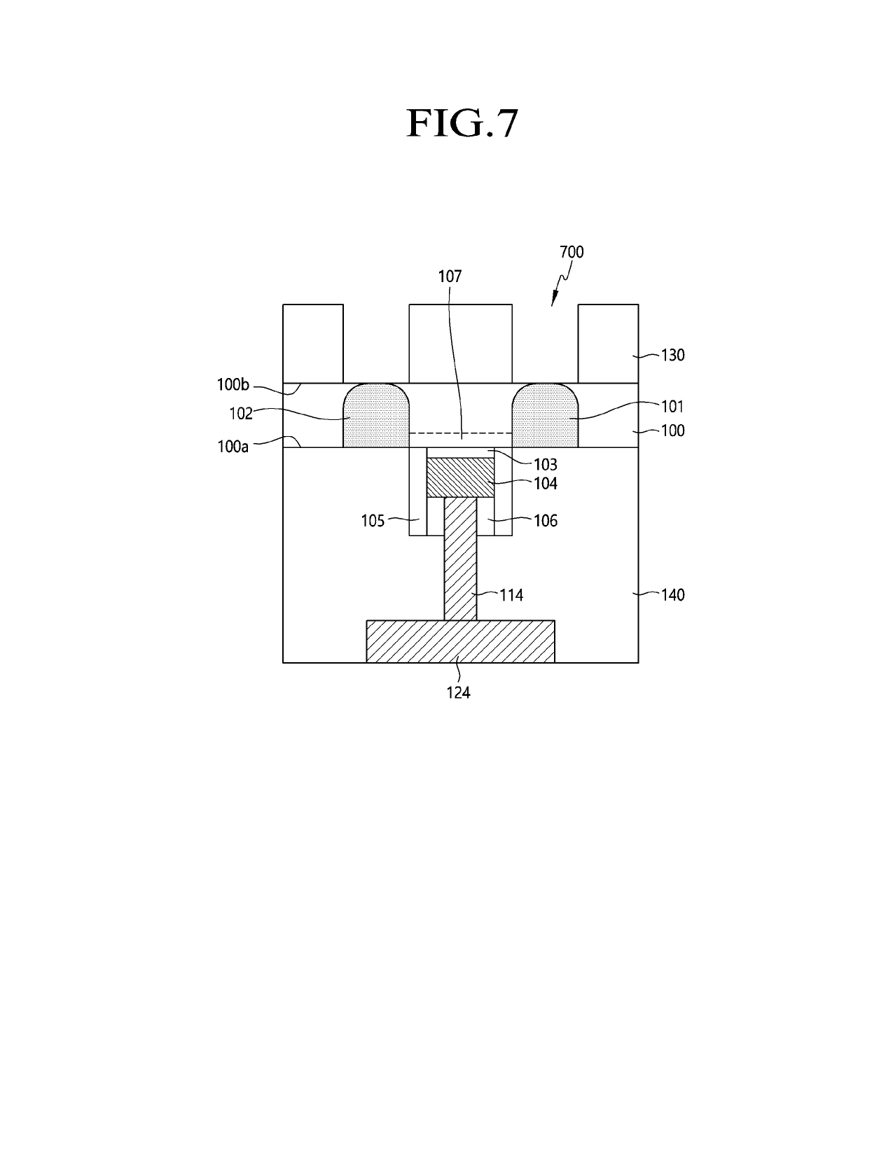

Referring to FIGS. 6 and 7, a first insulation layer 130 is formed on the substrate 100. After the first insulation layer 130 is formed, at least one first through hole 700 penetrating the first insulation layer 130 is formed. The process of forming the first through hole 700 includes an etching process. The first through hole 700 may expose one surface (e.g., the upper surface) of the source area 101 and the drain area 102. In an embodiment, the first through hole 700 may expose the second surface 100b of the substrate 100 where the source area 101 or the drain area 102 is not disposed.

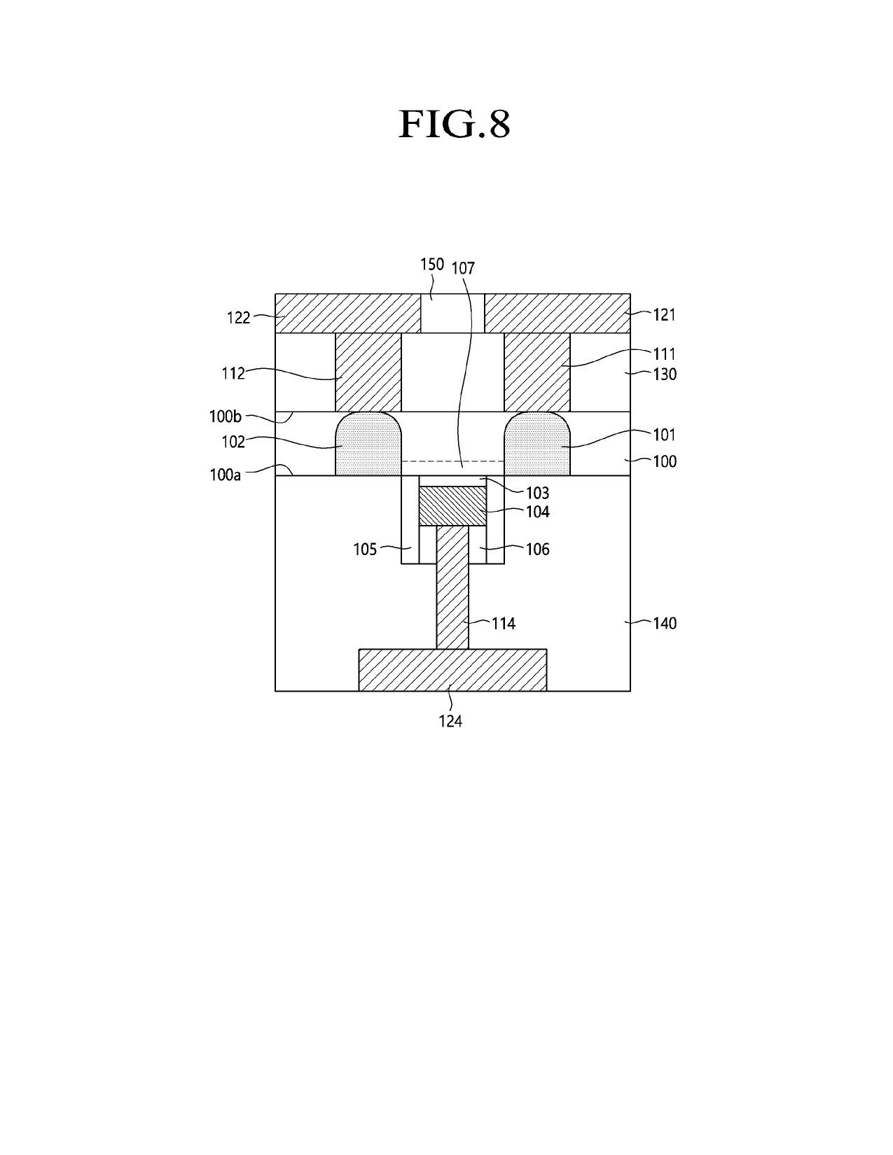

Referring to FIGS. 7 and 8, a source contact 111 and a drain contact 112 are formed in the first through hole 700. A third insulation layer 150 is formed on the source contact 111 and the drain contact 112. A source line 121 and a drain line 122 are formed on the source contact 111 and the drain contact 112, respectively, through the third insulation layer 150.

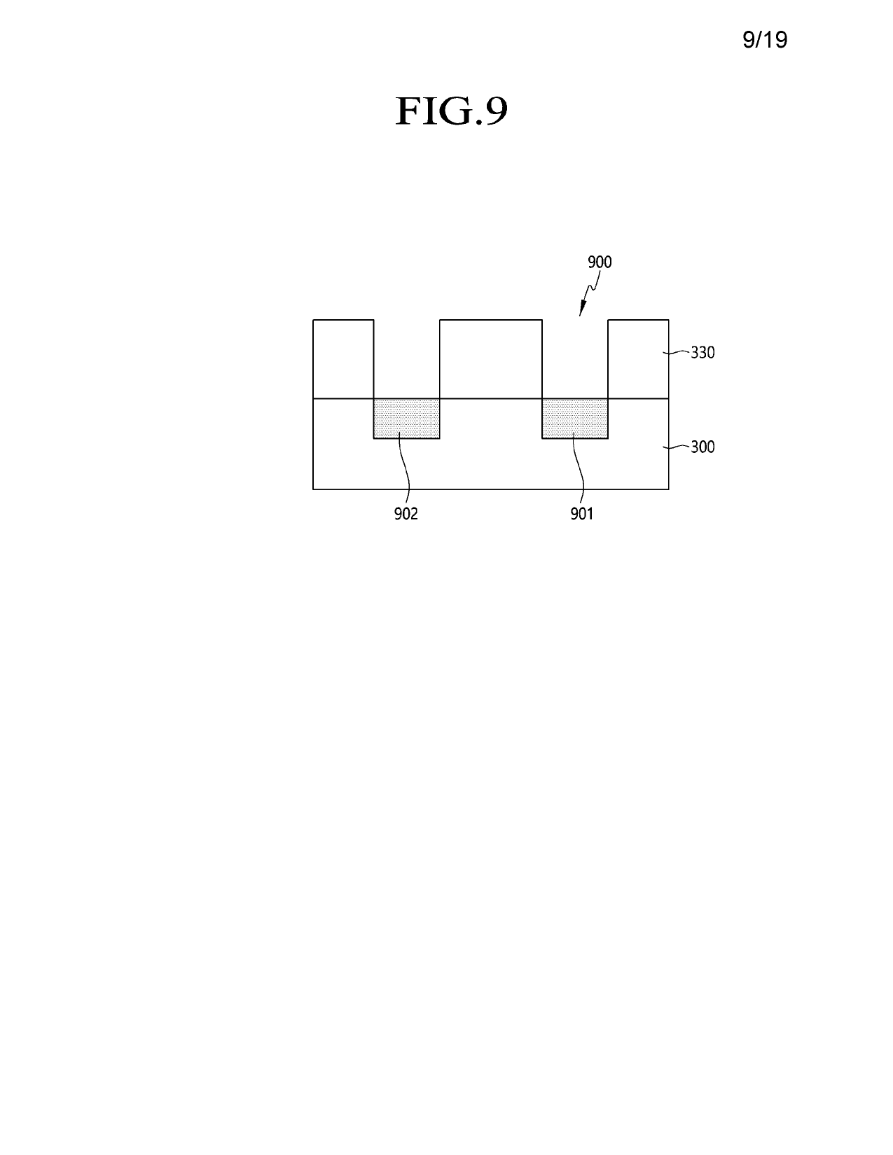

FIGS. 9 to 19 are views illustrating another method for manufacturing a semiconductor device according to embodiments of the present disclosure.

Referring to FIG. 9, a second substrate 300 having a third semiconductor area 901 and a fourth semiconductor area 902 is prepared.

The third semiconductor area 901 and the fourth semiconductor area 902 may be epitaxially grown layers. Each of the third semiconductor area 901 and the fourth semiconductor area 902 includes silicon doped with carbon, phosphorus, or arsenic, silicon germanium, or boron-doped silicon germanium depending on the type (e.g., N-type or P-type) of the transistor TR.

A first insulation layer 330 is formed on the second substrate 300. After the first insulation layer 330 is formed, at least one second through hole 900 penetrating the first insulation layer 330 is formed. The process of forming the second through hole 900 includes an etching process. The second through hole 900 may expose one surface (e.g., the upper surface) of the third semiconductor area 901 and the fourth semiconductor area 902.

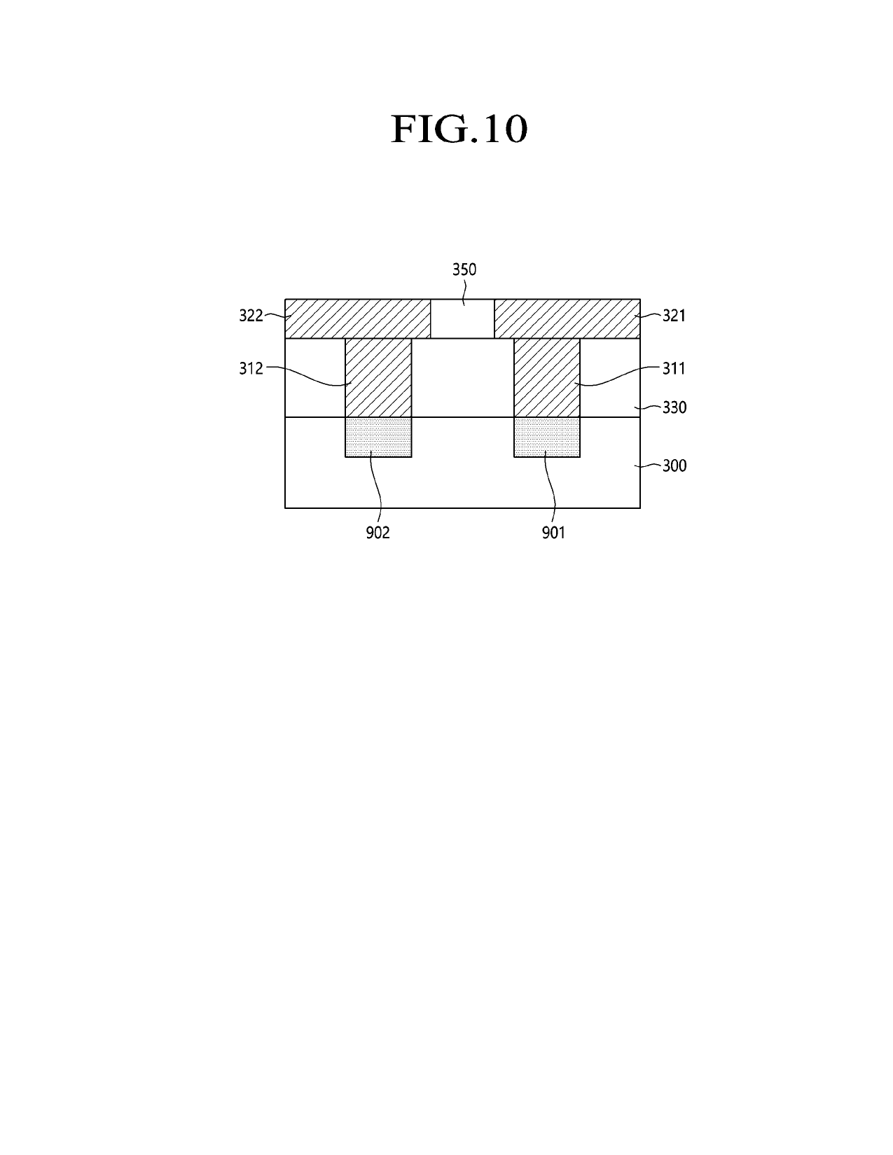

Referring to FIGS. 9 and 10, a source contact 311 and a drain contact 312 are formed in the second through hole 900. A third insulation layer 350 is formed on the source contact 311 and the drain contact 312. A source line 321 and a drain line 322 are formed on the source contact 311 and the drain contact 312, respectively, through the third insulation layer 350.

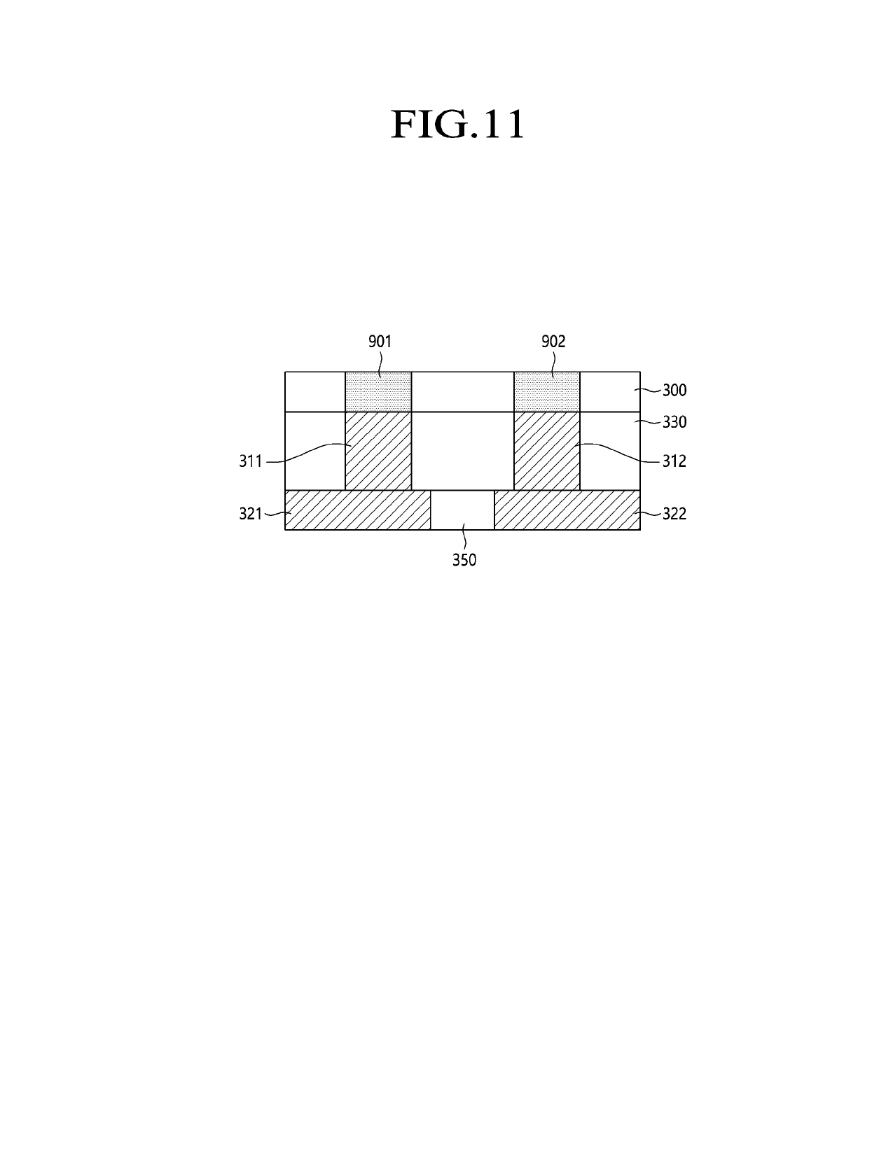

Referring to FIG. 11, the semiconductor device in FIG. 10 is flipped over. The lower portion of the second substrate 300 is removed to expose the third semiconductor area 901 and the fourth semiconductor area 902. The process of removing the lower portion of the second substrate 300 includes a chemical mechanical polishing (CMP) process or a grinding process.

In an embodiment, upper surfaces of the third semiconductor area 901 and the fourth semiconductor area 902 may form substantially the same plane as one surface (e.g., the upper surface) of the second substrate 300. In an embodiment, the widths of the third semiconductor area 901 and the fourth semiconductor area 902 on one surface (e.g., the upper surface) of the second substrate 300 may be the same as the widths of the third semiconductor area 901 and the fourth semiconductor area 902 on one surface (e.g., the lower surface) of the second substrate 300, respectively.

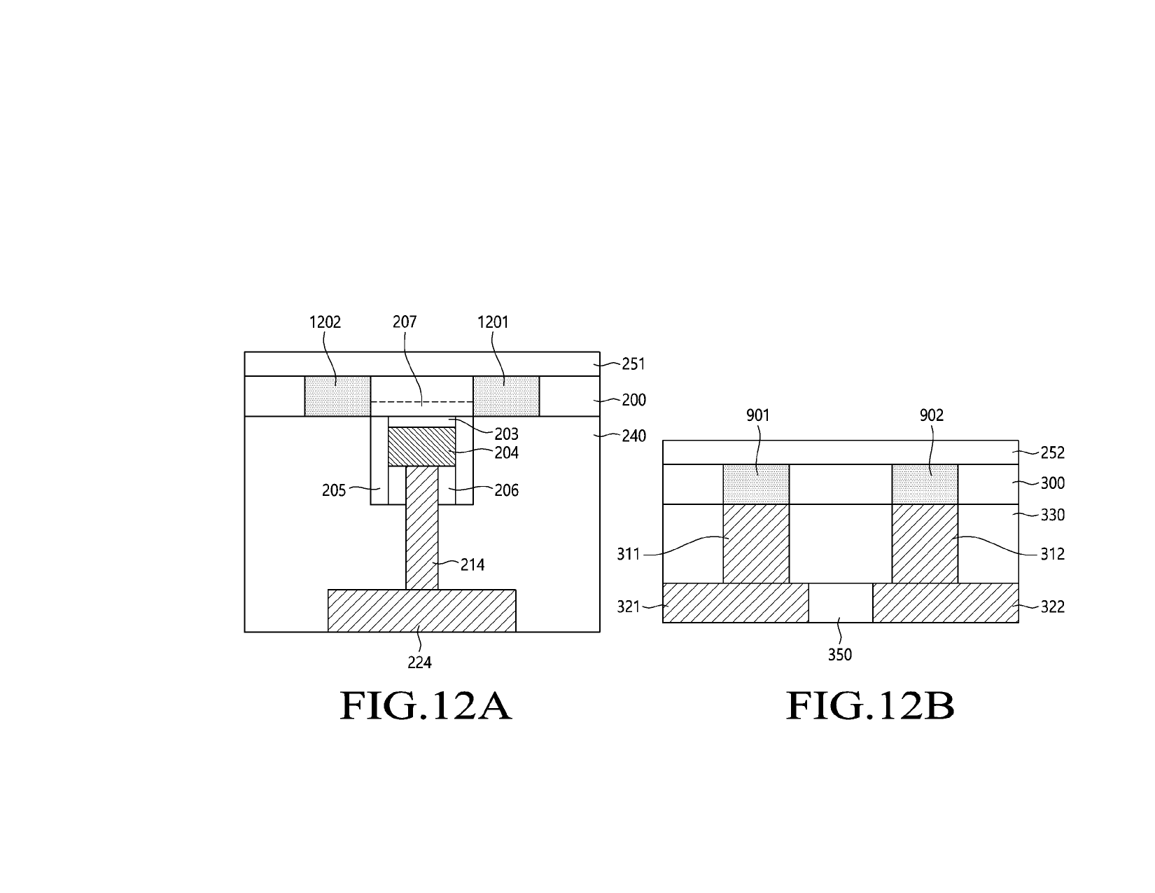

Referring to FIGS. 12A and 12B, a first substrate 200 having a channel area 207, and a first semiconductor area 1201 and a second semiconductor area 1202 connected to the channel area 207 is prepared. A gate insulation layer 203, a gate electrode 204, a gate capping layer 206, a spacer 205, a gate contact 214, and a gate line 224 formed on the first substrate 200 may be the same as the gate insulation layer 203, the gate electrode 204, the gate capping layer 206, the spacer 205, the gate contact 214, and the gate line 224 of the semiconductor device described with reference to FIG. 2, respectively.

A first bonding insulation layer 251 is formed on one surface (e.g., the upper surface) of the first substrate 200. A second bonding insulation layer 252 is formed on one surface (e.g., the upper surface) of the second substrate 300.

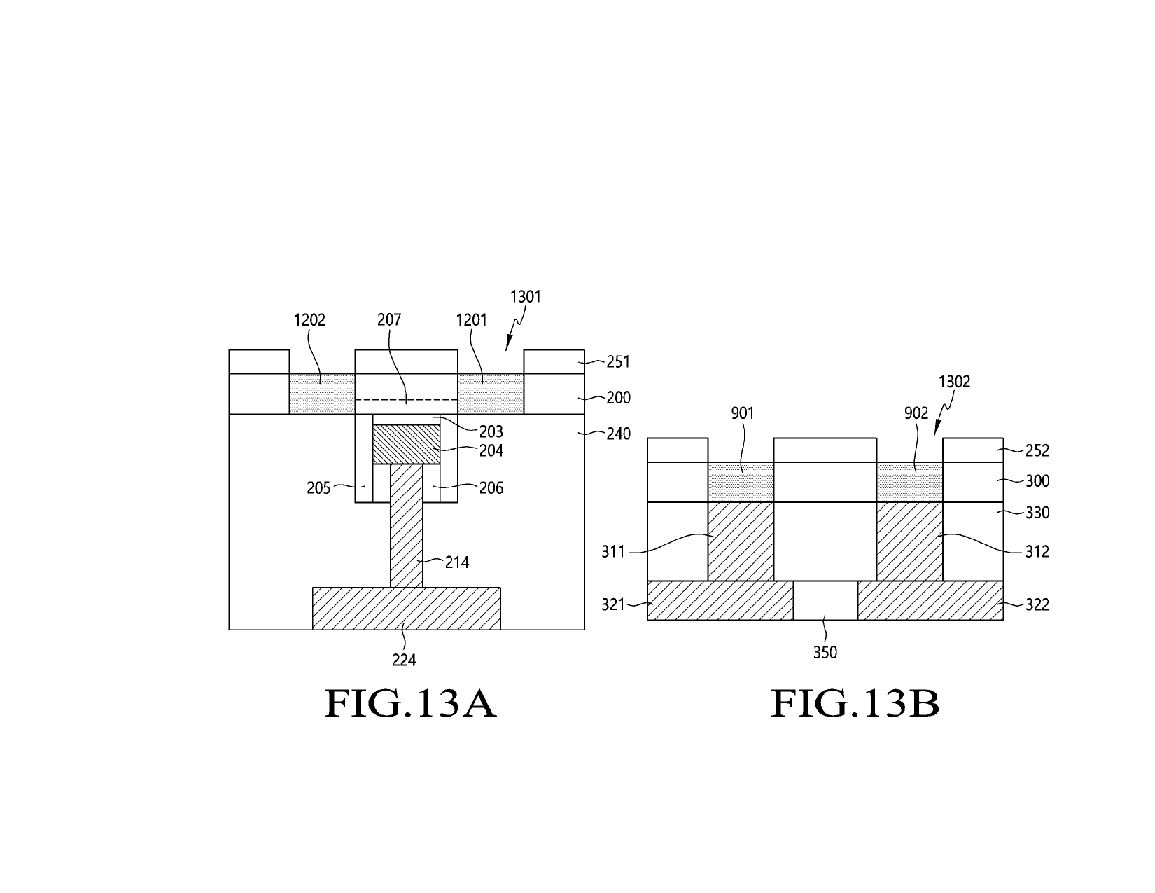

Referring to FIGS. 13A and 13B, at least one third through hole 1301 penetrating the first bonding insulation layer 251 is formed. The process of forming the third through hole 1301 includes an etching process. The third through hole 1301 may expose one surface (e.g., the upper surface) of the first semiconductor area 1201 and the second semiconductor area 1202.

At least one fourth through hole 1302 penetrating the second bonding insulation layer 252 is formed. The process of forming the fourth through hole 1302 includes an etching process. The fourth through hole 1302 may expose one surface (e.g., the upper surface) of the third semiconductor area 901 and the fourth semiconductor area 902.

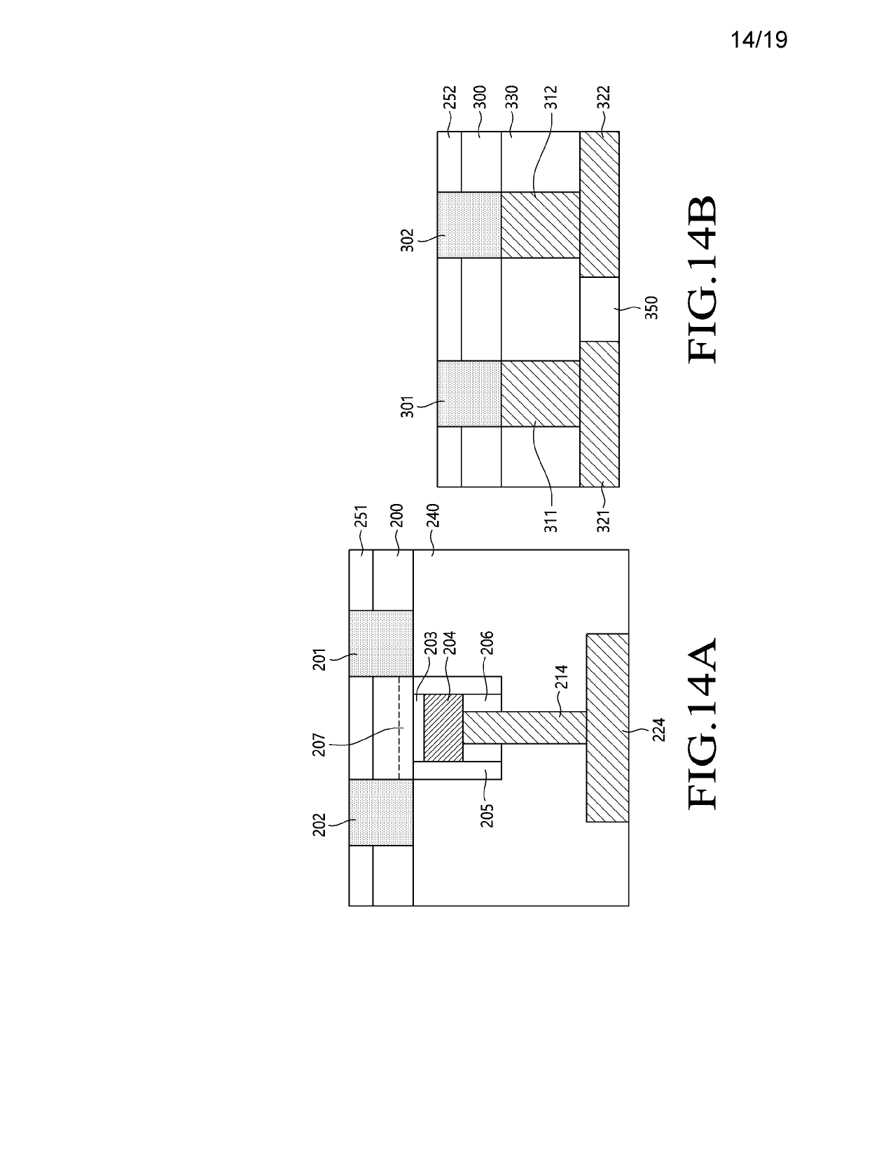

Referring to FIGS. 13A, 13B, 14A and 14B, a first source area 201, a first drain area 202, a second source area 301, and a second drain area 302 may be formed by epitaxially growing the first semiconductor area 1201, the second semiconductor area 1202, the third semiconductor area 901, and the fourth semiconductor area 902. The first source area 201 and the first drain area 202 may fill the inside of the third through hole 1301. The second source area 301 and the second drain area 302 may fill the inside of the fourth through hole 1302.

In an embodiment, one surface (e.g., the upper surface) of the first source area 201 and the first drain area 202 may form substantially the same plane as one surface (e.g., the upper surface) of the first bonding insulation layer 251. In an embodiment, one surface (e.g., the upper surface) of the second source area 301 and the second drain area 302 may form substantially the same plane as one surface (e.g., the upper surface) of the second bonding insulation layer 252.

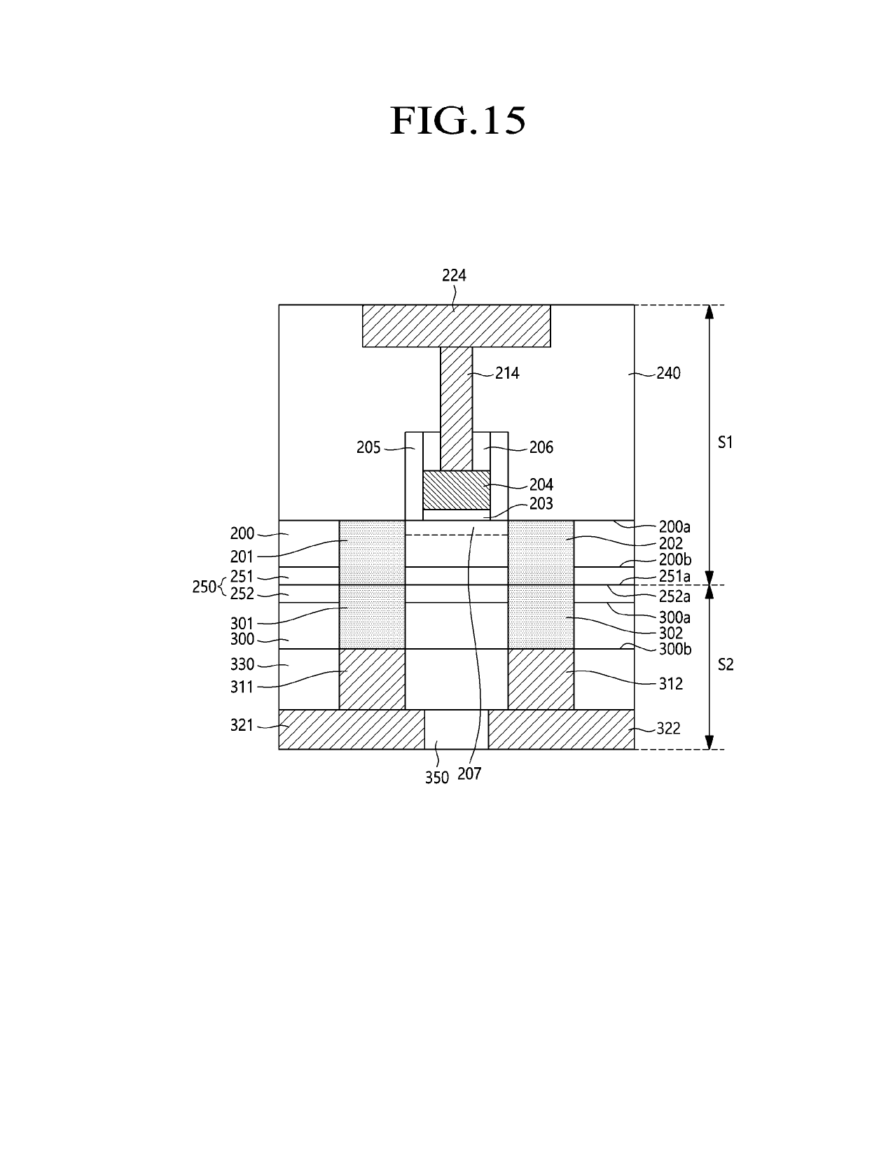

Referring to FIG. 15, the semiconductor device in FIG. 14A is flipped over. The first semiconductor structure S1 is bonded to the second semiconductor structure S2. For example, the lower surface of the first bonding insulation layer 251 is bonded to the upper surface of the second bonding insulation layer 252. The lower surface of the first source area 201 is connected to the upper surface of the second source area 301. The lower surface of the first drain area 202 is connected to the upper surface of the second drain area 302.

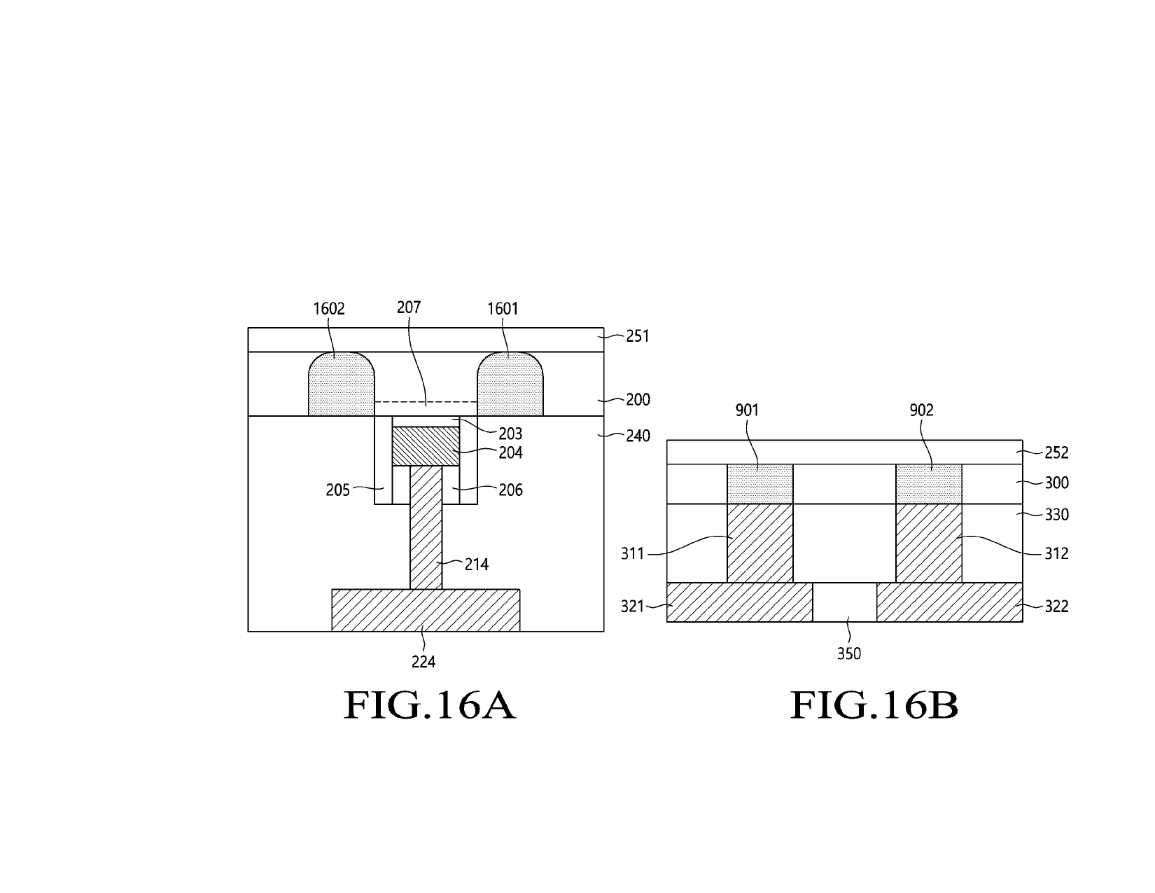

Referring to FIGS. 16A and 16B, a first substrate 200 having a channel area 207, and a first semiconductor area 1601 and a second semiconductor area 1602 connected to the channel area 207 is prepared. A gate insulation layer 203, a gate electrode 204, a gate capping layer 206, a spacer 205, a gate contact 214, and a gate line 224 formed on the first substrate 200 may be the same as the gate insulation layer 203, the gate electrode 204, the gate capping layer 206, the spacer 205, the gate contact 214, and the gate line 224 of the semiconductor device described with reference to FIG. 3, respectively.

In an embodiment, the widths of the first semiconductor area 1601 and the second semiconductor area 1602 on one surface (e.g., the upper surface) of the first substrate 200 may be thinner than the widths of the first semiconductor area 1601 and the second semiconductor area 1602 on one surface (e.g., the lower surface) of the first substrate 200, respectively.

The thickness of the first substrate 200 shown in FIG. 16A may be thicker than the thickness of the first substrate 200 shown in FIG. 12A. The thicknesses of the first semiconductor area 1601 and the second semiconductor area 1602 illustrated in FIG. 16A may be thicker than the thicknesses of the first semiconductor area 1201 and the second semiconductor area 1202 illustrated in FIG. 12A, respectively.

A first bonding insulation layer 251 is formed on the first substrate 200, the first semiconductor area 1601, and the second semiconductor area 1602. A second bonding insulation layer 252 is formed on the second substrate 300, the third semiconductor area 901, and the fourth semiconductor area 902. The second bonding insulation layer 252 on the second substrate 300, the third semiconductor area 901, and the fourth semiconductor area 902 may be the same as the second bonding insulation layer 252 on the second substrate 300, the third semiconductor area 901, and the fourth semiconductor area 902 described with reference to FIG. 12B, respectively.

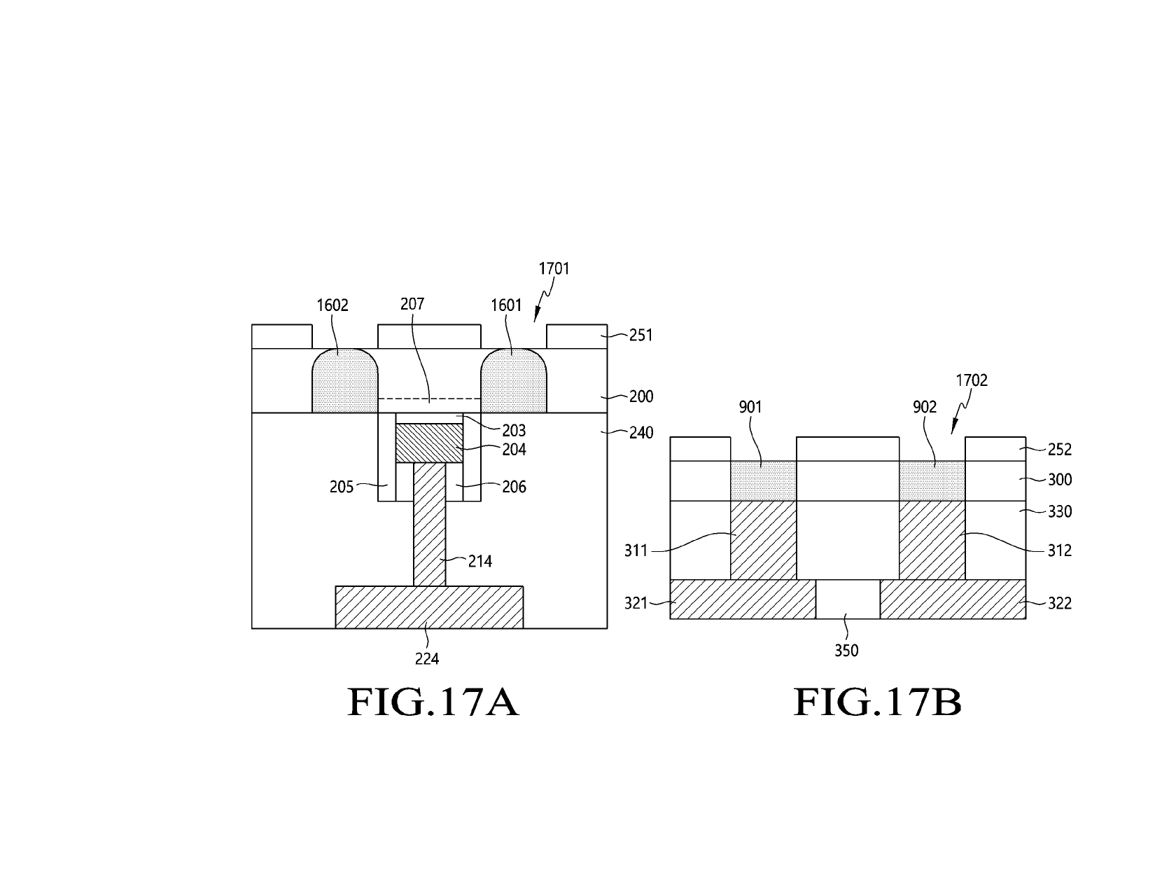

Referring to FIGS. 17A and 17B, at least one fifth through hole 1701 penetrating the first bonding insulation layer 251 is formed. The process of forming the fifth through hole 1701 includes an etching process. The fifth through hole 1701 may expose one surface (e.g., the upper surface) of the first semiconductor area 1601 and the second semiconductor area 1602. In an embodiment, the fifth through hole 1701 may expose at least a portion of one surface (e.g., the upper surface) of the first substrate 200.

At least one sixth through hole 1702 penetrating the second bonding insulation layer 252 is formed. The process of forming the sixth through hole 1702 includes an etching process. The sixth through hole 1702 may expose one surface (e.g., the upper surface) of the third semiconductor area 901 and the fourth semiconductor area 902.

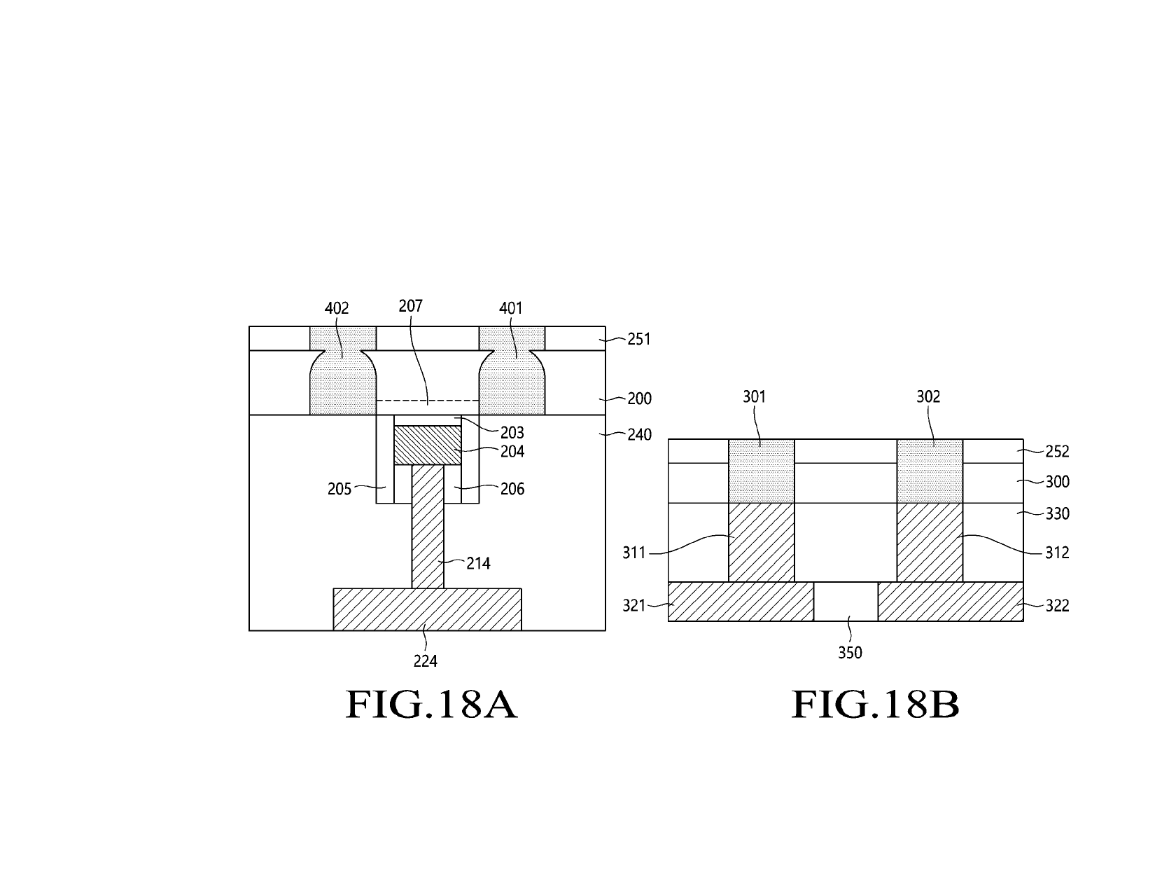

Referring to FIGS. 18A and 18B, a first source area 401, a first drain area 402, a second source area 301, and a second drain area 302 may be formed by epitaxially growing the first semiconductor area 1601, the second semiconductor area 1602, the third semiconductor area 901, and the fourth semiconductor area 902 of FIGS. 17A and 17B. The first source area 401 and the first drain area 402 may fill the inside of the fifth through hole 1701. The second source area 301 and the second drain area 302 may fill the inside of the sixth through hole 1702.

In an embodiment, one surface (e.g., the upper surface) of the first source area 401 and the first drain area 402 may form substantially the same plane as one surface (e.g., the upper surface) of the first bonding insulation layer 251. In an embodiment, one surface (e.g., the upper surface) of the second source area 301 and the second drain area 302 may form substantially the same plane as one surface (e.g., the upper surface) of the second bonding insulation layer 252. In an embodiment, the widths of the first source area 401 and the first drain area 402 on one surface (e.g., the upper surface) of the first substrate 200 may be thinner than the widths of the first source area 401 and the first drain area 402 on one surface (e.g., the lower surface) of the first substrate 200, respectively.

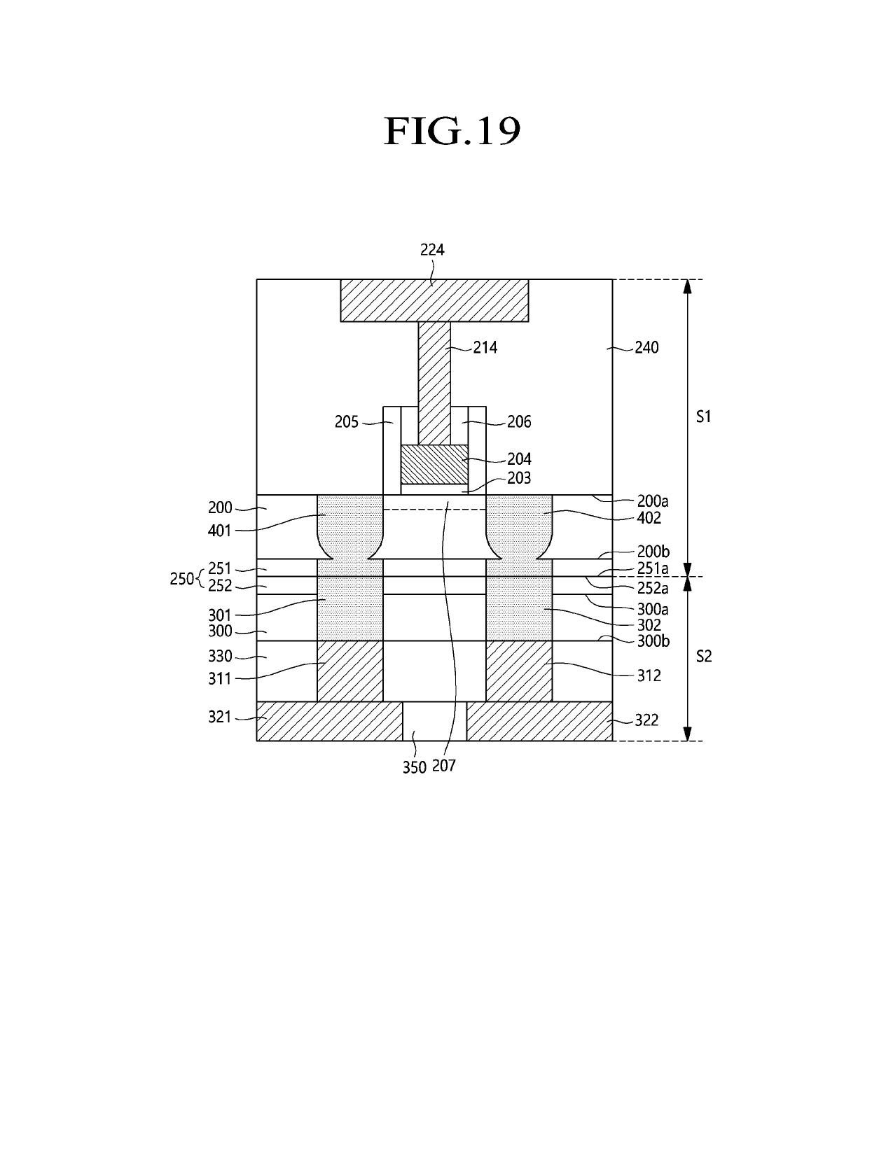

Referring to FIG. 19, the semiconductor device in FIGS. 18A is flipped over. The first semiconductor structure S1 is bonded to the second semiconductor structure S2. For example, the lower surface of the first bonding insulation layer 251 is bonded to the upper surface of the second bonding insulation layer 252. The lower surface of the first source area 401 is connected to the upper surface of the second source area 301. The lower surface of the first drain area 402 is connected to the upper surface of the second drain area 302.

Referring back to FIG. 1, the gate contact 114 is connected to the upper surface of the gate electrode 104 positioned on the first surface 100a of the substrate 100. The source contact 111 and the drain contact 112 are connected to the lower surfaces of the source area 101 and the drain area 102 forming the same plane as the second surface 100b of the substrate 100.

According to embodiments of the present disclosure, the gate contact 114 may be positioned in an opposite direction to the source contact 111 and the drain contact 112 with respect to the substrate 100. As a result, the distance between the gate contact 114 and the source contact 111, or the distance between the gate contact 114 and the drain contact 112 is greater than the distance between the gate contact 114 and the source contact 111, or the distance between the gate contact 114 and the drain contact 112 when the gate contact 114, the source contact 111, and the drain contact 112 are positioned in the same direction with respect to the substrate. Therefore, interference between the gate contact 114 and the source contact 111 and interference between the gate contact 114 and the drain contact 112 may be minimized. Therefore, even when the size of the transistor decreases due to high integration, the performance deterioration of the transistor due to interference between contacts may be prevented. Further, since the interference between the gate contact 114 and the source contact 111, and the interference between the gate contact 114 and the drain contact 112 is minimized, the width of each contact may not be reduced even if the size of the transistor TR decreases. Accordingly, a semiconductor device according to embodiments of the present disclosure may be advantageous for high integration.

The above-described embodiments are merely illustrative, and it will be appreciated by one of ordinary skill in the art that various changes may be made thereto without departing from the scope of the present disclosure. Accordingly, the embodiments set forth herein are provided for illustrative purposes, and not to limit the scope of the present disclosure. Furthermore, the embodiments may be combined to form additional embodiments.

What is claimed is:

1. A semiconductor device comprising:
a substrate;
a channel area formed in a part of the substrate;
a source area and a drain area spaced apart from each other penetrating the substrate, and connected to the channel area;
a gate insulation layer on the part of the substrate in a first direction;
a gate electrode disposed on the gate insulation layer;
a gate contact connected to the gate electrode; and
a source contact and a drain contact respectively connected to the source area and the drain area under the substrate in a second direction opposite to the first direction.

2. The semiconductor device of claim 1, wherein the substrate includes a first surface and a second surface facing each other, and
wherein upper surfaces of the source area and the drain area form the same plane as the first surface of the substrate, and lower surfaces of the source area and the drain area form the same plane or substantially the same plane as the second surface of the substrate.

3. The semiconductor device of claim 2, wherein the gate contact is connected to an upper surface of the gate electrode, and the source contact and the drain contact are connected to the lower surfaces of the source area and the drain area, respectively.

4. The semiconductor device of claim 2, wherein the source contact and the drain contact are connected to the second surface of the substrate in the second direction.

5. The semiconductor device of claim 1, wherein the substrate includes a first substrate where the channel area is disposed and a second substrate under the first substrate, and
wherein the first substrate and the second substrate are spaced apart from each other.

6. The semiconductor device of claim 5, further comprising a bonding insulation layer between the first substrate and the second substrate,
wherein the source area and the drain area penetrate the first substrate, the bonding insulation layer, and the second substrate.

7. The semiconductor device of claim 5, wherein the source contact and the drain contact are disposed under the second substrate.

8. A semiconductor device comprising:
a first semiconductor structure and a second semiconductor structure bonded to each other,
wherein the first semiconductor structure includes:
a first bonding insulation layer;
a first substrate disposed on the first bonding insulation layer;
a channel area formed in a part of the first substrate;
a first source area and a first drain area spaced apart from each other penetrating the first substrate and the first bonding insulation layer and connected to the channel area;
a gate electrode positioned on the first substrate; and
a gate contact connected to the gate electrode, and
wherein the second semiconductor structure includes:
a second bonding insulation layer connected to a lower surface of the first bonding insulation layer;
a second substrate disposed under the second bonding insulation layer;
a second source area and a second drain area penetrating the second substrate and the second bonding insulation layer and respectively connected to the first source area and the first drain area; and
a source contact and a drain contact connected to the second source area and the second drain area, respectively.

9. The semiconductor device of claim 8, wherein a lower surface of the first bonding insulation layer forms the same plane or substantially the same plane as lower surfaces of the first source area and the first drain area, and an upper surface of the second bonding insulation layer forms the same plane or substantially the same plane as upper surfaces of the second source area and the second drain area.

10. The semiconductor device of claim 8, wherein an upper surface of the first substrate forms the same plane or substantially the same plane as upper surfaces of the first source area and the first drain area, and a lower surface of the second substrate forms the same plane or substantially the same plane as lower surfaces of the second source area and the second drain area.

11. The semiconductor device of claim 8, wherein lower surfaces of the first source area and the first drain area are connected to upper surfaces of the second source area and the second drain area, respectively.

12. The semiconductor device of claim 8, wherein the second source area includes the same material as a material of the first source area, and the second drain area includes the same material as a material of the second source area.

13. The semiconductor device of claim 8, wherein the first source area, the first drain area, the second source area, and the second drain area are epitaxially grown layers.

14. A method for manufacturing a semiconductor device, the method comprising:
preparing a first substrate having an upper surface on which a channel area, and a first semiconductor area and a second semiconductor area connected to the channel area are formed;
forming, on the upper surface of the first substrate, a gate electrode and a gate contact connected to the gate electrode;
exposing lower surfaces of the first semiconductor area and the second semiconductor area; and
forming a source contact and a drain contact connected to the first semiconductor area and the second semiconductor area, respectively.

15. The method of claim 14, wherein the gate contact, the source contact and the drain contact are positioned in opposite directions with respect to the first substrate.

16. The method of claim 14, wherein the lower surfaces of the first semiconductor area and the second semiconductor area form the same plane as a lower surface of the first substrate by exposing the lower surfaces of the first semiconductor area and the second semiconductor area by removing the lower portion of the first substrate.

17. The method of claim 14, further comprising:
preparing a second substrate having an upper surface on which a third semiconductor area and a fourth semiconductor area are formed;
exposing lower surfaces of the third semiconductor area and the fourth semiconductor area;
forming a first bonding insulation layer on the lower surfaces of the first semiconductor area and the second semiconductor area;
forming a second bonding insulation layer on the lower surfaces of the third semiconductor area and the fourth semiconductor area; and
bonding the first bonding insulation layer and the second bonding insulation layer.

18. The method of claim 17, further comprising:
forming a first source area and a first drain area by epitaxially growing the first semiconductor area and the second semiconductor area between forming the first bonding insulation layer and bonding the first bonding insulation layer and the second bonding insulation layer; and
forming a second source area and a second drain area by epitaxially growing the third semiconductor area and the fourth semiconductor area between forming the second bonding insulation layer and bonding the first bonding insulation layer and the second bonding insulation layer.

19. The method of claim 18, wherein the first source area and the first drain area are connected to the second source area and the second drain area, respectively,
wherein the source contact and the drain contact are connected to the second source area and the second drain area, respectively, and
wherein the source contact and the drain contact are connected to the first source area and the first drain area through the second source area and the second drain area, respectively.

20. The method of claim 14, wherein the lower surfaces of the first semiconductor area and the second semiconductor area are exposed by removing a lower portion of the first substrate.
